(19) United States
(12) Patent Application Publication
(10) Pub. No.: US 2026/0271744 A1
(43) Pub. Date: Sep. 10, 2026

(54) CIRCUIT ASSEMBLY WITH A CIRCUIT CARRIER AND A SEMICONDUCTOR COMPONENT

(71) Applicant: Siemens Aktiengesellschaft, 80333 München (DE)

(72) Inventors: ALEXANDER HENSLER, Gerhardshofen (DE); JÖRG STROGIES, Berlin (DE); MATTHIAS HEIMANN, Potsdam (DE); BERND MÜLLER, Falkenberg (DE); PHILIPP OSCHMANN, Erlangen (DE); STEFAN PFEFFERLEIN, Heroldsberg (DE)

(73) Assignee: Siemens Aktiengesellschaft, 80333 München (DE)

(21) Appl. No.: 18/877,032

(22) PCT Filed: May 10, 2023
(86) PCT No.: PCT/EP2023/062337

§ 371 Date: Dec. 19, 2024

(30) Foreign Application Priority Data
Jun. 20, 2022 (EP) 22179922.4

(51) Int. Cl. H10W 70/40; H10W 40/47; H10W 40/60; H10W 40/77

(52) U.S. Cl. CPC H10W 70/461; H10W 40/47; H10W 40/611; H10W 40/77; H10W 70/456; H10W 70/481

(57) ABSTRACT

A circuit assembly includes a circuit carrier, a lead frame electrically connected to the circuit carrier, and a semiconductor component disposed between the circuit carrier and the lead frame and embodied as transistor including a control terminal connected to a first contact pad of the circuit carrier, a first load terminal connected to a second contact pad of the circuit carrier, and a second load terminal connected to the lead frame by bonding material. The control terminal and the first load terminal face the circuit carrier. The second load terminal faces the lead frame. A cooling body is disposed on a side of the lead frame facing away from the semiconductor component. An electrically insulating insulation element is disposed between the lead frame and the cooling body. A pressing unit presses the circuit carrier, the semiconductor component, the lead frame, the insulation element and the cooling body against one another.

The invention relates to a circuit assembly with a circuit carrier and a semiconductor component.

In the field of power electronics, semiconductor components such as switching elements are generally available in the form of power modules or as discrete packages. The semiconductor components are usually contacted using specific wire bonding technologies and the power modules are attached to a circuit carrier using soldered, spring or press-fit connections, for example. The use of bonding wires limits the maximum permissible current density through the semiconductor components. In addition, parasitic inductances occur, which limit the achievable switching speed of the switching elements.

WO 2020/249479 A1 discloses an electronic circuit comprising, among other things, a first circuit carrier, a second circuit carrier and a power-electronic semiconductor component. The semiconductor component has a top side which lies against an underside of the first circuit carrier and a lower side which lies against a top side of the second circuit carrier. The first circuit carrier has a via which electrically connects the top side of the first semiconductor component to a conductor track of the first circuit carrier. The second circuit carrier has, for example, an electrically conductive layer constituting its top side and an electrically insulating layer disposed on a side of the electrically conductive layer facing away from the first circuit carrier. The problem with such an arrangement of circuit carriers and semiconductor components is that the two circuit carriers may have very different coefficients of thermal expansion. After these two circuit carriers have been materially bonded, e.g. by soldering or sintering, this difference will result in significant warping of the composite structure once they have cooled down. Consequently, the second circuit carrier may not be able to make full surface contact with a heat sink, which will impair heat dissipation from the circuit. The differing expansion coefficients of the circuit carriers may cause cracks to form in the layers of the second circuit carrier, potentially leading to reliability issues and even failure of the entire circuit.

JP 2001 156225 A discloses a semiconductor device having a pair of heat radiating elements. Semiconductor chips are disposed between the heat radiating elements. The heat radiating elements are made of a metallic material whose electrical and/or thermal conductivity is greater than that of tungsten or molybdenum.

US 2020/343155 A1 discloses a power conversion device comprising two heat dissipators, a printed circuit board with a circuit pattern formed thereon, and a switching element having an electrode section electrically connected to the circuit pattern. A first insulation element is disposed between a first heat dissipator and the circuit board. A second insulation element is disposed between the second heat dissipator and the switching element.

DE 10 2014 205 958 A1 discloses a semiconductor switching element assembly for use in a vehicle, comprising a printed circuit board and a semiconductor switching element attached to the printed circuit board, which element is enclosed by a metallic cover attached to the printed circuit board. The metallic cover is in thermally conductive contact with a cooling device or can be brought into such contact.

EP 3 440 906 A1 discloses an electronic module comprising a printed circuit board, at least one integrated circuit mounted on the printed circuit board, and at least one EMI shield mounted on the printed circuit board. The at least one integrated circuit is mounted within a circumference defined by the shield.

The object of the invention is to provide an improved circuit assembly which overcomes these problems.

This object is inventively achieved by a circuit assembly having the features as claimed in claim 1.

Advantageous embodiments of the invention are set forth in the sub-claims.

A circuit assembly according to the invention comprises
a circuit carrier,
a lead frame,
a semiconductor component disposed between the circuit carrier and the lead frame,
a cooling body (heat sink) disposed on a side of the lead frame facing away from the semiconductor component,
an electrically insulating insulation element disposed between the lead frame and the cooling body, and
a pressing unit which is designed to press the circuit carrier, the semiconductor component, the lead frame, the insulation element and the cooling body against one another.

In contrast to the circuit assembly known from WO 2020/249479A1 , for example, the circuit assembly according to the invention has a circuit carrier and a lead frame between which the semiconductor component is disposed Instead of two circuit carriers between which the semiconductor component is disposed. In addition, the circuit assembly has an insulation element disposed between the lead frame and the cooling body. The lead frame and the insulation element assume the functions of the second circuit carrier of the circuit assembly known from WO 2020/249479A1 , namely the electrical contacting of the semiconductor component on the side of the semiconductor component facing the lead frame and the conduction of heat from the semiconductor component to the cooling body.

Decoupling the lead frame from the insulation element enables the problem of warping in the circuit assembly to be solved, namely by manufacturing the lead frame from a material with a coefficient of thermal expansion similar to that of the circuit carrier and by ensuring that the insulation element and lead frame are not materially bonded. This also significantly reduces the risk of cracking in the lead frame compared to cracking in an electrically conductive layer of a second circuit carrier and provides a potentially longer service life of the circuit assembly.

The pressing unit provides large contact surfaces independently of temperature and therefore good heat transfer between the cooling body, the insulation element and the lead frame and thus improved heat dissipation of the semiconductor component.

Replacing the second circuit carrier from WO 2020/249479 A1 by a combination of lead frame and insulation element also advantageously reduces the cost of the circuit assembly, as an expensive second circuit carrier is no longer required. In addition, the lead frame can be made significantly thicker than the electrically conductive layer of the second circuit carrier in WO 2020/249479A1 , resulting in improved heat spreading across the semiconductor component.

The formulation that the circuit assembly has a semiconductor component does not exclude the possibility that the circuit assembly comprises a plurality of semiconductor components, and is therefore to be understood as comprising at least one semiconductor component. The same applies to the formulations that the circuit assembly has a circuit carrier or a lead frame. For example, the circuit assembly can comprise a plurality of semiconductor components, each disposed between a circuit carrier and a lead frame, and an insulation element disposed between the cooling body and each lead frame. The circuit assembly can have one circuit carrier on which all the semiconductor components are disposed, or a plurality of circuit carriers on each of which at least one semiconductor component is disposed. Accordingly, the circuit assembly can have one lead frame for all the semiconductor components or a plurality of lead frames for at least one semiconductor component in each case. If the circuit assembly has a plurality of semiconductor components, at least one pair of said semiconductor components is electrically connected to form a half bridge, for example. Two semiconductor components can be connected, for example, via a circuit carrier on which both semiconductor components are disposed, or via another circuit carrier which is electrically connected to two circuit carriers on each of which one of the two semiconductor components is disposed.

In one embodiment of the invention, the insulation element is a ceramic plate. Said ceramic plate is made of aluminum oxide, aluminum nitride or silicon nitride, for example. An insulation element of this kind has high thermal conductivity and provides mechanical stability to counteract the pressing force exerted by the pressing unit.

In another embodiment of the invention, the insulation element is an insulating film. Said Insulating film is typically made of a silicone-based material. Due to its flexibility, an insulating film is advantageously largely unaffected by temperature changes and the pressing force exerted by the pressing unit and is therefore also suitable as an insulation element.

In another embodiment of the invention, the cooling body has a recess into which the insulation element is inserted. The recess advantageously determines the position of the insulation element, particularly if the insulation element is not materially bonded to the cooling body.

In another embodiment of the invention, the insulation element is not materially bonded to either the cooling body or the lead frame. As already explained above, a material bond between the insulation element and the cooling body or the lead frame is undesirable, as it would impair the pressing unit's ability to press the insulation element flexibly against the lead frame and the cooling body, independently of temperature changes of other components of the circuit assembly.

In another embodiment of the invention, a heat-conducting medium is disposed between the insulation element and the cooling body and/or between the insulation element and the lead frame, The heat-conducting medium is a heat-conducting oil, for example. The heat-conducting medium advantageously increases the heat transfer between the insulation element and the cooling body and/or between the Insulation element and the lead frame, thereby improving in particular the heat dissipation of the semiconductor component.

In another embodiment of the invention, the lead frame and the circuit carrier have similar coefficients of thermal expansion. This prevents warping of the lead frame and the circuit carrier caused by large differences in the coefficients of thermal expansion of the lead frame and the circuit carrier.

In another embodiment of the invention, the lead frame is made of copper. This embodiment of the invention is particularly advantageous if the first circuit carrier is a printed circuit board, since conventional printed circuit boards have a coefficient of thermal expansion similar to that of copper.

In another embodiment of the invention, the pressing unit has at least one screw connection which connects the cooling body to the circuit carrier or to a pressure plate which is disposed on a side of the circuit carrier facing away from the cooling body. A screw connection of this kind provides a simple, cost-effective, and flexibly adjustable design for the pressing unit.

In another embodiment of the invention, the circuit carrier is a printed circuit board, in particular a multilayer printed circuit board. The particular advantage of the circuit carrier being a printed circuit board is that the semiconductor component can be connected to conductor tracks and vias running in or on the printed circuit board.

In another embodiment of the invention, the semiconductor component has a first load terminal, which is disposed on a side of the semiconductor component facing the circuit carrier and is electrically connected to a contact pad of the circuit carrier, and a second load terminal, which is disposed on a side of the semiconductor component facing the lead frame and is electrically connected to the lead frame. In other words, the semiconductor component has load terminals disposed on opposite sides, which are each electrically contacted with the circuit carrier or with the lead frame. This provides contacting of the semiconductor component that is similar to the contacting known from WO 2020/249479A1 .

In another embodiment of the invention, the semiconductor component is a transistor, a diode or a thyristor. A circuit assembly according to the invention is suitable for all these semiconductor components, since all these semiconductor components can be designed such that their load terminals can be disposed on opposite sides of the semiconductor component.

The features, characteristics and advantages of the present invention described above and the manner in which they are achieved will become clearer and readily comprehensible in conjunction with the following description of exemplary embodiments which will be explained in more detail with reference to the accompanying drawings in which:

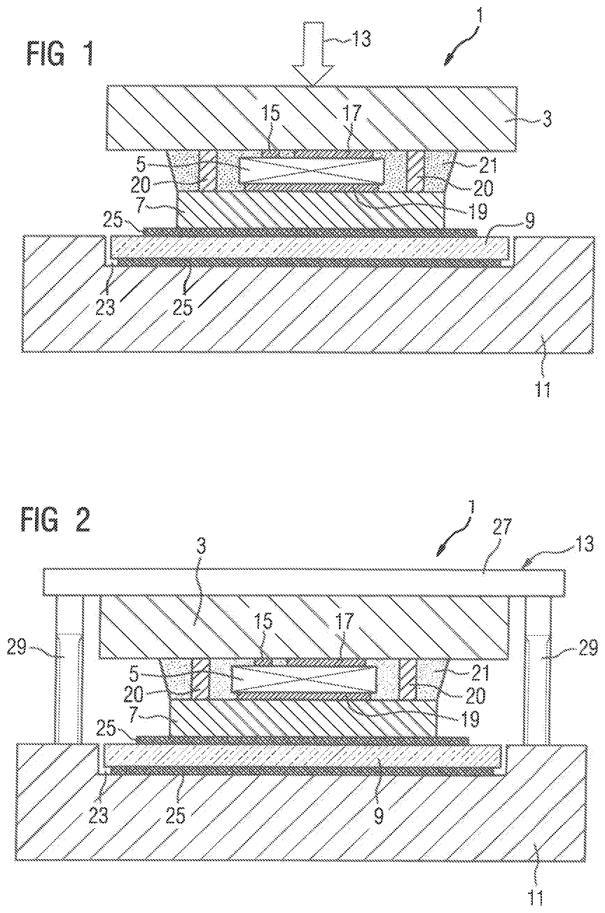

FIG. 1 shows a schematic sectional view of a first exemplary embodiment of a circuit assembly,

FIG. 2 shows a schematic sectional view of a second exemplary embodiment of a circuit assembly.

Corresponding parts are identified by the same reference characters in the figures.

FIG. 1 (FIG. 1) shows a schematic sectional view of a first exemplary embodiment of a circuit assembly 1.

The circuit assembly 1 comprises a circuit carrier 3, a semiconductor component 5, a lead frame 7, an insulation element 9, a cooling body 11 and a pressing unit 13.

The semiconductor component 5 is disposed between the circuit carrier 3 and the lead frame 7. In the exemplary embodiment shown, the semiconductor component 5 is a transistor having a control terminal, a first load terminal and a second load terminal. The control terminal and the first load terminal face the circuit carrier 3, while the second load terminal faces the lead frame 7. In other exemplary embodiments, the semiconductor component 5 can be, for example, a diode or a thyristor. If the semiconductor component 5 is a diode, it has no control terminal, only two load terminals.

The control terminal of the semiconductor component 5 is connected to a first contact pad 15 of the circuit carrier 3. The first load terminal of the semiconductor component 5 is connected to a second contact pad 17 of the circuit carrier 3. The first contact pad 15 and the second contact pad 17 are disposed on a side of the circuit carrier 3 facing the semiconductor component 5. The second load terminal of the semiconductor component 5 is connected to the lead frame 7 by a bonding material 19, e.g. a solder or sinter material.

The circuit carrier 3 is, for example, a multilayer printed circuit board with vias connecting each contact pad 15, 17 to at least one conductor track on the printed circuit board.

The lead frame 7 is made of a material that has a similar coefficient of thermal expansion to that of the circuit carrier 3. If the circuit carrier 3 is a printed circuit board, the lead frame 7 can be made of copper, for example. The lead frame 7 is also connected to the circuit carrier 3 via electrically conductive connections 20. The remaining space between the lead frame 7 and the circuit carrier 3 is filled with an encapsulating material 21, such as a casting resin.

The cooling body 11 and the insulation element 9 are disposed on a side of the lead frame 7 facing away from the semiconductor component 5. On its side facing the lead frame, the cooling body 11 has a recess 23 with dimensions exceeding those of the lead frame 7. The insulation element 9, the dimensions of which also exceed those of the lead frame 7, Is inserted into the recess 23. The insulation element 9 is thus disposed between the lead frame 7 and the cooling body 11 in the recess 23 in the cooling body 11.

A heat-conducting medium 25 is disposed between the insulation element 9 and the cooling body 11, and also between the insulation element 9 and the lead frame 7. The heat-conducting medium 25 is, for example, a heat-conducting oil. The Insulation element 9 is therefore not bonded to either the cooling body 11 or the lead frame 7, but is merely inserted into the recess 23 of the cooling body 11.

The Insulation element 9 is made of an electrically insulating material having good thermal conductivity. For example, the insulation element 9 is a ceramic plate. The ceramic plate is typically made of aluminum oxide, aluminum nitride or silicon nitride. Alternatively, the Insulation element 9 is an insulating film made of a silicone-based material, for example.

The pressing unit 13 is designed to press the combined structure comprising the circuit carrier 3, the semiconductor component 5 and the lead frame 7 against the insulation element 9 and the cooling body 11. In FIG. 1, the pressing unit 13 is only represented schematically by an arrow symbol which indicates the direction of a pressing force exerted by the pressing unit 13.

FIG. 2 (FIG. 2) shows a schematic sectional view of a second exemplary embodiment of a circuit assembly 1. The only difference between this exemplary embodiment and that shown in FIG. 1 is that it schematically illustrates a specific embodiment of the pressing unit 13. In this exemplary embodiment, the pressing unit 13 has a pressure plate 27 and screw connections 29. The pressure plate 27 is disposed on a side of the circuit carrier 3 facing away from the cooling body 11. The screw connections 29 connect the pressure plate 27 to the cooling body 11 and exert, via the pressure plate 27, a pressing force which presses the combined structure comprising the circuit carrier 3, the semiconductor component 5 and the lead frame 7 against the insulation element 9 and the cooling body 11.

If the circuit carrier 3 is sufficiently stable, the second exemplary embodiment shown in FIG. 2 can be modified to create a third exemplary embodiment in which the pressure plate 27 is omitted and the screw connections 29 connect the circuit carrier 3 directly to the cooling body 11.

Although the invention has been illustrated and described in detail by preferred exemplary embodiments, the invention is not limited by the examples disclosed and other variations will be apparent to a person skilled in the art without departing from the scope of protection sought for the invention.

What is claimed

1-14. (canceled)

15. A circuit assembly, comprising
a circuit carrier embodied as a printed circuit board, said circuit carrier including a first contact pad and a second contact pad;
a lead frame connected to the circuit carrier via electrically conducting connections;
a semiconductor component disposed between the circuit carrier and the lead frame and embodied as a transistor which includes a control terminal connected to the first contact pad of the circuit carrier, a first load terminal connected to the second contact pad of the circuit carrier, and a second load terminal, with the control terminal and the first load terminal facing the circuit carrier and with the second load terminal facing the lead frame;
a bonding material connecting the second load terminal of the semiconductor component to the lead frame;
a cooling body disposed on a side of the lead frame which side faces away from the semiconductor component,
an electrically insulating insulation element disposed between the lead frame and the cooling body; and
a pressing unit designed to press the circuit carrier, the semiconductor component, the lead frame, the insulation element and the cooling body against one another.

16. The circuit assembly of claim 15, wherein the printed circuit board is a multilayer printed circuit board.

17. The circuit assembly of claim 15, wherein the bonding material is a solder or a sinter material.

18. The circuit assembly of claim 15, wherein the insulation element is a ceramic plate.

19. The circuit assembly of claim 18, wherein the ceramic plate is made of aluminum oxide, aluminum nitride or silicon nitride.

20. The circuit assembly of claim 15, wherein the insulation element is an insulating film.

21. The circuit assembly of claim 20, wherein the insulating film is made of a silicone-based material.

22. The circuit assembly of claim 15, wherein the cooling body includes a recess into which the insulation element is inserted.

23. The circuit assembly of claim 15, wherein the insulation element is not materially bonded to either the cooling body or the lead frame.

24. The circuit assembly of claim 15, further comprising a heat-conducting medium disposed between the insulation element and the cooling body and/or between the insulation element and the lead frame.

25. The circuit assembly of claim 24, wherein the lead frame is connected over a full surface to the insulation element by way of the heat-conducting medium.

26. The circuit assembly of claim 24, wherein the heat-conducting medium is a heat-conducting oil.

27. The circuit assembly of claim 15, wherein the lead frame and the circuit carrier have similar coefficients of thermal expansion.

28. The circuit assembly of claim 15, wherein the lead frame is made of copper.

29. The circuit assembly of claim 15, wherein the pressing unit includes a screw connection which connects the cooling body to the circuit carrier.

30. The circuit assembly of claim 15, further comprising a pressure plate disposed on a side of the circuit carrier which side faces away from the cooling body, said pressing unit including a screw connection which connects the cooling body to the pressure plate.

31. The circuit assembly of claim 15, wherein the first load terminal of the semiconductor component is disposed on a side of the semiconductor component which side faces the circuit carrier and is electrically connected to the second contact pad of the circuit carrier, and wherein the second load terminal of the semiconductor component is disposed on a side of the semiconductor component which side faces the lead frame and is electrically connected to the lead frame.

32. The circuit assembly of claim 15, wherein the lead frame has a planar surface on a side facing the insulation element and a planar surface on a side facing the semiconductor component.
